(19) United States
(12) Patent Application Publication
(10) Pub. No.: US 2023/0049464 A1
(43) Pub. Date: Feb. 16, 2023

(54) Ruthenium-Containing Films Deposited On Ruthenium-Titanium Nitride Films And Methods Of Forming The Same

(71) Applicant: MERCK PATENT GMBH, Darmstadt (DE)

(72) Inventors: Guo LIU, Haverhill, MA (US); Jacob WOODRUFF, Lexington, MA (US)

(21) Appl. No.: 17/792,041

(22) PCT Filed: Jan. 14, 2021
(86) PCT No.: PCT/EP2021/050632

§ 371 Date: Jul. 11, 2022

Related U.S. Application Data
(60) Provisional application No. 62/961,835, filed on Jan. 16, 2020.

(51) Int. Cl. C23C 16/34; C23C 16/02; C23C 16/455

(52) U.S. Cl. CPC C23C 16/34; C23C 16/0272; C23C 16/45553; B82Y 30/00

(57) ABSTRACT

Methods of forming ruthenium-containing films by atomic layer deposition and/or chemical vapor deposition are provided. The methods include a first step of forming a first film on a surface of the substrate and a second step of forming the ruthenium-containing film on at least a portion of the first film. The first step includes delivering a titanium precursor and a first nitrogen-containing co-reactant to the substrate and delivering a first ruthenium precursor and a second nitrogen-containing co-reactant to the substrate to form the first film. The second step includes delivering a second ruthenium precursor and a third co-reactant to the substrate. Ruthenium-containing films are also provided.

### FIELD

The present invention relates to ruthenium-containing films deposited on ruthenium-titanium nitride (RuTiN) films and methods of forming the ruthenium-containing films.

### BACKGROUND

Various precursors are used to form thin films and a variety of deposition techniques has been employed. Such techniques include reactive sputtering, ion-assisted deposition, chemical vapor deposition (CVD) (also known as metalorganic CVD or MOCVD), and atomic layer deposition (also known as atomic layer epitaxy). CVD and ALD processes are increasingly used as they have the advantages of enhanced compositional control, high film uniformity, and effective control of doping. Moreover, CVD and ALD processes provide excellent conformal step coverage on highly non-planar geometries associated with modern microelectronic devices.

CVD is a chemical process whereby precursors are used to form a thin film on a substrate surface. In a typical CVD process, the precursors are passed over the surface of a substrate (e.g., a wafer) in a low pressure or ambient pressure reaction chamber. The precursors react and/or decompose on the substrate surface creating a thin film of deposited material. Plasma can be used to assist in reaction of a precursor or for improvement of material properties. Volatile by-products are removed by gas flow through the reaction chamber. The deposited film thickness can be difficult to control because it depends on coordination of many parameters such as temperature, pressure, gas flow volumes and uniformity, chemical depletion effects, and time.

ALD is a chemical method for the deposition of thin films. It is a self-limiting, sequential, unique film growth technique based on surface reactions that can provide precise thickness control and deposit conformal thin films of materials provided by precursors onto surfaces substrates of varying compositions. In ALD, the precursors are separated during the reaction. The first precursor is passed over the substrate surface producing a monolayer on the substrate surface. Any excess unreacted precursor is pumped out of the reaction chamber. A second precursor or co-reactant is then passed over the substrate surface and reacts with the first precursor, forming a second monolayer of film over the first-formed monolayer of film on the substrate surface. Plasma may be used to assist with reaction of a precursor or co-reactant or for improvement in materials quality. This cycle is repeated to create a film of desired thickness.

Thin films, and in particular thin metal-containing films, have a variety of important applications, such as in nanotechnology and the fabrication of semiconductor devices. Examples of such applications include capacitor electrodes, gate electrodes, adhesive diffusion barriers, and integrated circuits.

The continual decrease in the size of microelectronic components has increased the need for improved thin film technologies. Further, there is a need for deposition of ruthenium as next generation metal electrodes, caps or liners in logic and memory semiconductor manufacturing. Furthermore, while metal nitride liners, such as titanium nitride or tungsten nitride, can be used to improve ruthenium nucleation with decreased surface roughness, metal nitride liners have significantly higher resistivity than pure metals, which is undesirable. Therefore, processes for forming ruthenium-containing films on metal-containing liners are needed, which can be performed at lower temperatures using halide-free organometallic precursors to achieve lower resistivity films with improved ruthenium nucleation.

### SUMMARY OF THE INVENTION

Thus, provided herein are methods of forming a ruthenium-containing film on a substrate. The method includes a first step of forming a first film on a surface of the substrate and a second step of forming ruthenium-containing film on at least a portion of the first film. The first step includes delivering a titanium precursor and a first nitrogen-containing co-reactant to the substrate and delivering a first ruthenium precursor and a second nitrogen-containing co-reactant to the substrate to form the first film. The second step includes delivering a second ruthenium precursor and a third co-reactant to the substrate and/or the first film.

In other embodiments, a ruthenium-containing film is provided. The ruthenium-containing film includes a first film disposed on a surface of a substrate and the ruthenium-containing film disposed on at least a portion of the first film. The first film includes a first reaction product of a titanium precursor and a first nitrogen-containing co-reactant, and a second reaction product of a first ruthenium precursor and a second nitrogen-containing co-reactant. The ruthenium-containing film includes a third reaction product of a second ruthenium precursor and a third co-reactant.

Other embodiments, including particular aspects of the embodiments summarized above, will be evident from the detailed description that follows.

### BRIEF DESCRIPTION OF THE DRAWINGS

FIG. 1A is a graphical representation of as-deposited ruthenium-titanium nitride (RuTiN) film growth rate (nm/cycle) vs. Ti/Ru cycle ratio for RuTiN films grown on three substrates, Al₂O₃, SiO₂, and WCN according to Example 1.

FIG. 1B is a graphical representation of annealed RuTiN film growth rate (nm/cycle) vs. Ti/Ru cycle ratio for annealed RuTiN films grown on three substrates, Al₂O₃, SiO₂, and WCN according to Example 1.

FIG. 1C is a graphical representation comparing growth rate (nm/cycle) vs. Ti/Ru cycle ratio for as-deposited RuTiN films grown on SiO₂ and annealed RuTiN films grown on SiO₂ from FIGS. 1A and 1B.

FIG. 2A is a graphical representation comparing resistivity (μΩ-cm) vs. Ti/Ru cycle ratio for as-deposited RuTiN films grown on Al₂O₃ (“as-dep.”) and annealed RuTiN films grown on Al₂O₃.

FIG. 2B is a graphical representation comparing resistivity (μΩ-cm) vs. Ti/Ru cycle ratio for as-deposited RuTiN films grown on SiO₂ (“as-dep.”) and annealed RuTiN films grown on SiO₂.

FIG. 2C is a graphical representation comparing resistivity (μΩ-cm) vs. Ti/Ru cycle ratio for as-deposited RuTiN films grown on WCN (“as-dep.”) and annealed RuTiN films grown on WCN.

FIG. 3A is a graphical representation of an XPS depth profile for an annealed RuTiN film formed on SiO₂ with a Ti/Ru cycle ratio of 1:2.

FIG. 4A is a graphical representation comparing resistivity (μΩ-cm) vs. Ti/Ru cycle ratio for thick as-deposited RuTiN films (13-20 nm) grown on Al₂O₃, SiO₂ and WCN according to Example 4.

FIG. 4B is a graphical representation comparing resistivity (μΩ-cm) vs. Ti/Ru cycle ratio for thin as-deposited RuTiN films (2-5 nm) grown on Al₂O₃, SiO₂ and WCN according to Example 4.

FIG. 5A is a graphical representation comparing resistivity (μΩ-cm) vs. Ti/Ru cycle ratio for thick annealed RuTiN films (13-20 nm) grown on Al₂O₃, SiO₂ and WCN according to Example 5.

FIG. 5B is a graphical representation comparing resistivity (μΩ-cm) vs. Ti/Ru cycle ratio for thin annealed RuTiN films (2-5 nm) grown on Al₂O₃, SiO₂ and WCN according to Example 5.

FIGS. 6A-6E are scanning electron microscope (SEM) images of surfaces of annealed RuTiN films formed on SiO₂ having a Ti/Ru cycle ratio of 1:4, 1:3, 1:2, 2:3, and 1:1, respectively.

FIGS. 7A-7C are SEM images of surfaces of annealed RuTiN films formed on 4 nm Al₂O₃/100 nm SiO₂ having a Ti/Ru cycle ratio of 1:3, 1:2, and 1:1, respectively. FIG. 7D is an SEM images of a surface of annealed RuTiN films having a Ti/Ru cycle ratio of 1:1 on 25 nm Al₂O₃/native SiO₂ (referred to as “thick Al₂O₃” or “Al₂O₃_thick on Si”).

FIG. 7E is a graphical representation of AFM roughness (nm) vs. Ti/Ru cycle ratio for annealed films formed on various substrates.

FIGS. 8A-8E are SEM images of surfaces of as-deposited Ru films formed directly on a 100 nm SiO₂ substrate (no liner) and Ru films formed in-situ on an as-deposited RuTiN film liner on 100 nm SiO₂ or 4 nm Al₂O₃/100 nm SiO₂.

FIG. 9A is a graphical representation of AFM roughness (nm) vs. Ru thickness (nm) measured by X-ray Fluorescence (XRF) for Ru films were formed via ALD on the following liners on 100 nm SiO₂: RuTiN, TiN, TiN_OEM, and WCN. A Ru film was also formed directly on 100 nm SiO₂ without a liner.

FIG. 9B is a graphical representation of AFM roughness (nm) vs. X-ray Fluorescence (XRF) Ru thickness (nm) for Ru films were formed via ALD on the following liners on 4 nm Al₂O₃/100 nm SiO₂: RuTiN, TiN, and TiN on 25 nm Al₂O₃/Si with native SiO₂ (Al₂O₃/Si) A Ru film was also formed directly on 4 nm Al₂O₃/100 nm SiO₂ without a liner.

FIGS. 10A-10E are SEM images of surfaces of RuTiN films formed on 100 nm SiO₂ or 4 nm Al₂O₃/100 nm SiO₂.

FIG. 10F is a graphical representation of AFM roughness (nm) vs estimated thickness (nm) of the RuTiN liner for annealed RuTiN films formed on 100 nm SiO₂ or 4 nm Al₂O₃/100 nm SiO₂.

FIGS. 11A and 11B are cross-section SEM images of a via structure coated with 6.5 nm Ru on top of a 3 nm in-situ RuTiN liner (1:2 cycle ratio), deposited at 225° C.

### DETAILED DESCRIPTION

Before describing several exemplary embodiments of the present technology, it is to be understood that the technology is not limited to the details of construction or process steps set forth in the following description. The present technology is capable of other embodiments and of being practiced or being carried out in various ways.

The inventors have discovered processes including two steps to improve ruthenium deposition and films formed therefrom. The processes may include depositing a first film or a liner, such as a RuTiN containing film, on a substrate using a titanium precursor as described herein, a first nitrogen-containing co-reactant as described herein, a first ruthenium precursor as described herein, and a second nitrogen-containing co-reactant. A ruthenium-containing film can be formed on the first film by delivering a second ruthenium precursor as described herein and a third co-reactant. Advantageously, the processes described herein can be performed at lower temperatures, for example, less than or equal to 350° C., and with halide-free precursors. The first film formed can have lower resistivity compared with other metal nitride liners as a result of ruthenium doping in the first film. The deposition processes described herein were discovered to provide smoother ruthenium films with a smaller grain size and lower resistivity compared to current deposition processes for forming ruthenium thin films, including current ALD processes to form ruthenium thin films as well as ALD processes using metal nitride liners.

### Definitions

For purposes of this invention and the claims hereto, the numbering scheme for the Periodic Table Groups is according to the IUPAC Periodic Table of Elements.

The term “and/or” as used in a phrase such as “A and/or B” herein is intended to include “A and B”, “A or B”, “A”, and “B”.

The terms “substituent”, “radical”, “group”, and “moiety” may be used interchangeably.

As used herein, the terms “metal-containing complex” (or more simply, “complex”) and “precursor” are used interchangeably and refer to a metal-containing molecule or compound which can be used to prepare a metal-containing film by a deposition process such as, for example, ALD or CVD. The metal-containing complex may be deposited on, adsorbed to, decomposed on, delivered to, and/or passed over a substrate or surface thereof, as to form a metal-containing film.

As used herein, the term “metal-containing film” includes not only an elemental metal film as more fully defined below, but also a film which includes a metal along with one or more elements, for example a metal nitride film, metal silicide film, a metal carbide film and the like. As used herein, the terms “elemental metal film” and “pure metal film” are used interchangeably and refer to a film which consists of, or consists essentially of, pure metal. For example, the elemental metal film may include 100% pure metal or the elemental metal film may include at least about 70%, at least about 80%, at least about 90%, at least about 95%, at least about 96%, at least about 97%, at least about 98%, at least about 99%, at least about 99.9%, or at least about 99.99% pure metal along with one or more impurities. Unless context dictates otherwise, the term “metal film” shall be interpreted to mean an elemental metal film.

As used herein, the term “deposition process” is used to refer to any type of deposition technique, including but not limited to, CVD and ALD. In various embodiments, CVD may take the form of conventional (i.e., continuous flow) CVD, liquid injection CVD, plasma-enhanced CVD, or photo-assisted CVD. CVD may also take the form of a pulsed technique, i.e., pulsed CVD. ALD is used to form a metal-containing film by vaporizing and/or passing at least one metal complex disclosed herein over a substrate surface. For conventional ALD processes see, for example, George S. M., et al. J. Phys. Chem., 1996, 100, 13121-13131. In other embodiments, ALD may take the form of conventional (i.e., pulsed injection) ALD, liquid injection ALD, photo-assisted ALD, plasma-assisted ALD, or plasma-enhanced ALD. The term “vapor deposition process” further includes various vapor deposition techniques described in Chemical Vapour Deposition: Precursors, Processes, and Applications; Jones, A. C.; Hitchman, M. L., Eds. The Royal Society of Chemistry: Cambridge, 2009; Chapter 1, pp 1-36.

The term “alkyl” refers to a saturated hydrocarbon chain of 1 to about 8 carbon atoms in length, such as, but not limited to, methyl, ethyl, propyl and butyl. The alkyl group may be straight-chain or branched-chain. For example, as used herein, propyl encompasses both n-propyl and iso-propyl; butyl encompasses n-butyl, sec-butyl, iso-butyl and tert-butyl. Further, as used herein, “Me” refers to methyl, and “Et” refers to ethyl.

### Ruthenium-Containing Films and Methods of Forming the Same

As stated above, ruthenium-containing films and methods of forming ruthenium-containing films are provided herein. The ruthenium-containing film can include a first film (or a liner) disposed on a surface of a substrate and the ruthenium-containing film disposed on at least a portion of the first film. The first film can include a first reaction product of a titanium precursor and a first nitrogen-containing co-reactant and a second reaction product of a first ruthenium precursor and a second nitrogen-containing co-reactant. In any embodiment, the first film can comprise ruthenium-titanium nitride (RuTiN). In any embodiment, the first film may include a first layer adjacent to the surface of the substrate, wherein the first layer comprises the first reaction product. The first layer and/or the first reaction product may also optionally include dissociated moieties of the titanium precursor, dissociated moieties of the first nitrogen-containing co-reactant, or a combination thereof. In some embodiments, the first film can include a second layer adjacent to the first layer, wherein the second layer comprises the second reaction product. The second layer and/or the second reaction product may also optionally include dissociated moieties of the first ruthenium precursor, dissociated moieties of the second nitrogen-containing co-reactant, or a combination thereof. Additionally or alternatively, the first film can include ruthenium as a dopant therein. For example, the first film can include the first reaction product, for example, present as the first layer, which is doped with ruthenium. Additionally or alternatively, the first film can include the first reaction product, for example, present as the first layer, and the second reaction product, for example, present as the second layer, wherein the first layer, the second layer, or both are ruthenium-doped. Plasma may be used to enhance reaction of a precursors or coreactants or improve film quality.

In any embodiment, the ruthenium-containing film can comprise a third reaction product of a second ruthenium precursor and a third co-reactant and optionally, dissociated moieties of the second ruthenium precursor, dissociated moieties of the third co-reactant, or a combination thereof. It is contemplated herein, that the first film, the first layer, the second layer, and the ruthenium-containing film can each be continuous or discontinuous layers.

A method of preparing the above-described ruthenium-containing film may comprise a first step and a second step. In any embodiment, the first step can include forming a first film (or a liner) on a surface of a substrate by delivering a titanium precursor and a first nitrogen-containing co-reactant to the substrate. The first step further includes delivering a first ruthenium precursor and a second nitrogen-containing co-reactant to the substrate. In various aspects, the first film can comprise a first reaction product as described above and a second reaction product as described above. In further aspects, the first film can include a first layer as described above, a second layer as described above, or a combination thereof. Additionally or alternatively, the first film can include ruthenium as a dopant therein.

In any embodiment, the second step can include delivering a second ruthenium precursor and a third co-reactant to the substrate to form a ruthenium-containing film on at least a portion of the first film. The ruthenium-containing film can comprise a third reaction product as described above.

In any embodiment, the first step, the second step, or a combination there can include use of plasma. Use of plasma can, for example, enhance reaction of one or more of a titanium precursor, a first ruthenium precursor, a second ruthenium precursor, a first nitrogen-containing co-reactant, a second nitrogen-containing co-reactant, and a third co-reactant. Additionally or alternatively, use of plasma can improve film quality.

In any embodiment, the titanium precursor corresponds in structure to Formula I:

[R¹R²N]₄Ti (Formula I)

wherein R¹ and R² are each independently a C₁-C₆-alkyl. In some embodiments, R¹ and R² are each independently a C₁-C₄-alkyl or a C₁-C₂-alkyl. Examples of suitable titanium precursors include, but are not limited to tetrakis(dimethylamido)titanium (also known as tetrakis(dimethylamino)titanium) (TDMAT), tetrakis(ethylmethylamido)titanium (also known as tetrakis(ethylmethylamino)titanium), and tetrakis(diethylamido) titanium (also known as tetrakis(diethylamino)titanium).

In any embodiment, the first ruthenium precursor comprises (η⁴-2,3-dimethylbuta-1,3-diene)tricarbonylruthenium ((DMBD)Ru(CO)₃), (η⁴-buta-1,3-diene)tricarbonylruthenium ((BD)Ru(CO)₃, (1,3-cyclohexadienyl)tricarbonylruthenium ((CHD)Ru(CO)₃), (η⁴-2-methylbuta-1,3-diene)tricarbonylruthenium, or triruthenium dodecacarbonyl Ru₃(CO)₁₂.

In any embodiment, the second ruthenium precursor comprises (η⁴-2,3-dimethylbuta-1,3-diene)tricarbonylruthenium ((DMBD)Ru(CO)₃), (η⁴-buta-1,3-diene)tricarbonylruthenium ((BD)Ru(CO)₃, (1,3-cyclohexadienyl)tricarbonylruthenium ((CHD)Ru(CO)₃), (η⁴-2-methylbuta-1,3-diene)tricarbonylruthenium, triruthenium dodecacarbonyl Ru₃(CO)_{12,} or another Ru(0) or Ru(II) ruthenium precursor such as (ethylbenzyl)(1-ethyl-1,4-cyclohexadienyl)ruthenium(0) (Ru(EtBz)(EtCHD)), bis(ethylcyclopentadienyl)ruthenium(II) (Ru(EtCp)₂), (cyclopentadienyl)(ethyl)biscarbonylruthenium(0) (Cp(Et)Ru(CO)₂), or (N,N′-diisopropylacetoamidinato)biscarbonylruthenium(II) ((amidinate)Ru(CO)₂). In any embodiment, the first ruthenium precursor and the second ruthenium precursor can be the same.

In some embodiments, the titanium precursor, the first ruthenium precursor, the second ruthenium precursor, or a combination thereof may be dissolved in a suitable solvent such as a hydrocarbon or an amine solvent to facilitate the vapor deposition process. Appropriate hydrocarbon solvents include, but are not limited to, aliphatic hydrocarbons, such as hexane, heptane and nonane; aromatic hydrocarbons, such as toluene and xylene; and aliphatic and cyclic ethers, such as diglyme, triglyme, and tetraglyme. Examples of appropriate amine solvents include, without limitation, octylamine and N,N-dimethyldodecylamine. For example, the titanium precursor, the first ruthenium precursor, the second ruthenium precursor, or a combination may be dissolved in toluene to yield a solution with a concentration from about 0.05 M to about 1 M.

In alternative embodiments, the titanium precursor, the first ruthenium precursor, the second ruthenium precursor, or a combination may be delivered “neat” (undiluted by a carrier gas) to a substrate surface.

Thus, the precursors disclosed herein utilized in these methods may be liquid, solid, or gaseous. Typically, the ruthenium precursors are liquids or solids at ambient temperatures with a vapor pressure sufficient to allow for consistent transport of the vapor to the process chamber.

The first nitrogen-containing co-reactant and the second nitrogen-containing co-reactant can each independently be selected from the group consisting of NH₃, alkylamine, hydrazine, alkylhydrazine, and a combination thereof. In various aspects, the alkylhydrazine may be a C₁-C₈-alkylhydrazine, a C₁-C₄-alkylhydrazine, or a C₁-C₂-alkylhydrazine. For example, the alkyl hydrazine may be methylhydrazine, ethylhydrazine, propylhydrazine, or butylhydrazine (including tertiary-butylhydrazine).

In any embodiment, the third co-reactant can be selected from the group consisting of hydrogen, hydrogen plasma, nitrogen plasma, ammonia plasma, oxygen, air, water, H₂O₂, ozone, i-PrOH, t-BuOH, N₂O, ammonia, an alkylamine, a hydrazine, a borane, a silane, ozone, and a combination of any two or more thereof. In some embodiments, the third co-reactant may be a third nitrogen-containing co-reactant, for example, selected from the group consisting of NH₃, an alkylamine, hydrazine, alkylhydrazine, and a combination thereof.

In various aspects, the substrate surface can comprise a metal, a dielectric material, a metal oxide material, or a combination thereof. The dielectric material can be a low-κ dielectric or a high-κ dielectric. Examples of suitable dielectric materials include, but are not limited to SiO₂, SiN, and a combination thereof. Examples of suitable metal oxide materials include, but are not limited to HfO_{2,} ZrO₂, SiO₂, Al₂O₃, TiO₂, and combinations thereof. Other suitable substrate materials include, but are not limited to crystalline silicon, Si(100), Si(111), glass, strained silicon, silicon on insulator (SOI), doped silicon or silicon oxide(s) (e.g., carbon doped silicon oxides), germanium, gallium arsenide, tantalum, tantalum nitride, aluminum, copper, ruthenium, titanium, titanium nitride, tungsten, tungsten nitride, tungsten carbonitride (WCN), and any number of other substrates commonly encountered in nanoscale device fabrication processes (e.g., semiconductor fabrication processes). As will be appreciated by those of skill in the art, substrates may be exposed to a pretreatment process to polish, etch, reduce, oxidize, hydroxylate, anneal and/or bake the substrate surface. In one or more embodiments, the substrate surface contains a hydrogen-terminated surface.

The methods provided herein encompass various types of ALD and/CVD processes such as, but not limited to, continuous or pulsed injection processes, liquid injection processes, photo-assisted processes, plasma-assisted, and plasma-enhanced processes. For example, the first step and the second can be an ALD or a CVD process.

In some embodiments, conventional or pulsed CVD is used to form a first film as described herein and/or a ruthenium-containing film as described herein by vaporizing and/or passing the titanium precursor, the first ruthenium precursor, and/or the second ruthenium precursor, all disclosed herein, over a substrate surface. For conventional CVD processes see, for example Smith, Donald (1995). Thin-Film Deposition: Principles and Practice. McGraw-Hill.

In other embodiments, photo-assisted CVD is used to form a first film as described herein and/or a ruthenium-containing film as described herein by vaporizing and/or passing the titanium precursor, the first ruthenium precursor, and/or the second ruthenium precursor, all disclosed herein, over a substrate surface.

In some embodiments, conventional (i.e., pulsed injection) ALD is used to form a first film as described herein and/or a ruthenium-containing film as described herein by vaporizing and/or passing the titanium precursor, the first ruthenium precursor, and/or the second ruthenium precursor, all disclosed herein, over a substrate surface. For conventional ALD processes see, for example, George S. M., et al. J. Phys. Chem., 1996, 100, 13121-13131.

In other embodiments, liquid injection ALD is used to form a first film as described herein and/or a ruthenium-containing film as described herein by vaporizing and/or passing the titanium precursor, the first ruthenium precursor, and/or the second ruthenium precursor, all disclosed herein, over a substrate surface, wherein the aforementioned precursor is delivered to the reaction chamber by direct liquid injection as opposed to vapor draw by a bubbler. For liquid injection ALD processes see, for example, Potter R. J., et al., Chem. Vap. Deposition, 2005, 11(3), 159-169.

In other embodiments, photo-assisted ALD is used to form a first film as described herein and/or ruthenium-containing film as described herein by vaporizing and/or passing at least one precursor disclosed herein over a substrate surface. For photo-assisted ALD processes see, for example, U.S. Pat. No. 4,581,249.

In other embodiments, plasma-assisted or plasma-enhanced ALD is used to form a first film as described herein and/or a ruthenium-containing film as described herein by vaporizing and/or passing the titanium precursor, the first ruthenium precursor, and/or the second ruthenium precursor, all disclosed herein, over a substrate surface.

In further embodiments, the first step, for example during an ALD process, can include a super cycle including a titanium cycle and a ruthenium cycle. The titanium cycle can include delivering the titanium precursor, the first nitrogen-containing co-reactant, and a purge gas to the substrate. For example, the titanium precursor can be pulsed for 0.01-1 second, followed by delivery of a purge gas for 5-15 seconds, followed by pulsing the first nitrogen-containing co-reactant for 0.001-1 second and followed by delivery of a purge gas for 5-15 seconds. The ruthenium cycle can include delivering the first ruthenium precursor, the second nitrogen-containing co-reactant, and the purge gas to the substrate. For example, the first ruthenium precursor can be pulsed for 0.01-1 second, followed by delivery of a purge gas for 5-15 seconds, followed by pulsing the second nitrogen-containing co-reactant for 0.001-1 second and followed by delivery of a purge gas for 5-15 seconds.

A super cycle may include “m” number of titanium cycles followed by “n” number of ruthenium cycles, wherein m and n can each range from 1 to 100 cycles, 1 to 75 cycles, 1 to 50 cycles, 1 to 25 cycles, 1 to 10 cycles, or 1 to 5 cycles. The ratio of titanium cycles to ruthenium cycles can range from 1:1 to 2:12 or from 1:1 to 2:10. Depending on the ratio of titanium cycles to ruthenium cycles, the first film may have a Ti:Ru concentration ratio of about 1:10 to about 10:1.

In some embodiments, the super cycle can include 1 titanium cycle followed by from 1 to 50 ruthenium cycles, 1 to 25 ruthenium cycles, or 1 to 10 ruthenium cycles. Alternatively, the super cycle can include 2 titanium cycles followed by 3 ruthenium cycles. The total number of super cycles can range from 1 to 100, 1 to 75, 1 to 50, 1 to 25, 1 to 10, or 1 to 5.

In various aspects, the second step can include a further ruthenium cycle including delivering the second ruthenium precursor, the third co-reactant, and the purge gas to the substrate. For example, the third ruthenium precursor can be pulsed for 0.01-1 second, followed by delivery of a purge gas for 5-15 seconds, followed by pulsing the third co-reactant for 0.001-1 second and followed by delivery of a purge gas for 5-15 seconds. Any suitable purge gas can be used in the first and second steps, for example, nitrogen, hydrogen and a noble gas, e.g., helium, neon, argon, krypton, xenon, etc.

The reaction time, temperature and pressure for the methods described herein are selected to create the first film and the ruthenium-containing film on the surface of the substrate. The reaction conditions will be selected based on the properties of the titanium precursor, the first ruthenium precursor, and the second ruthenium precursor. The deposition can be carried out at atmospheric pressure but is more commonly carried out at a reduced pressure. The vapor pressure of the titanium precursor, the first ruthenium precursor, and the second ruthenium precursor should be high enough to be practical in such applications. The substrate temperature should be low enough to keep the bonds between the metal atoms at the surface intact and to prevent thermal decomposition of gaseous reactants. However, the substrate temperature should also be high enough to keep the source materials (i.e., the reactants) in the gaseous phase and to provide sufficient activation energy for the surface reaction. The appropriate temperature depends on various parameters, including the particular titanium precursor, the first ruthenium precursor, and the second ruthenium precursor used and the pressure. In some embodiments, the first step, the second step, or both may be performed at temperature of less than or equal to about 350° C., less than or equal to about 300° C., less than or equal to about 275° C., less than or equal to about 250° C., less than or equal to about 225° C., or about 200° C.; or from about 150° C. to about 350° C., preferably from about 200° C. to about 250° C. The aforementioned temperatures are understood to represent substrate temperature. In any embodiment, the first step, the second step, or both may be performed in inert atmospheres, for example, in argon atmospheres.

The properties of a specific titanium precursor, first ruthenium precursor, and second ruthenium precursor for use in the deposition methods disclosed herein can be evaluated using methods known in the art, allowing selection of appropriate temperature and pressure for the reaction. In general, lower molecular weight and the presence of functional groups that increase the rotational entropy of the ligand sphere result in a melting point that yields liquids at typical delivery temperatures and increased vapor pressure.

A titanium precursor, a first ruthenium precursor, and a second ruthenium precursor for use in the deposition methods will have all of the requirements for sufficient vapor pressure, sufficient thermal stability at the selected substrate temperature and sufficient reactivity to produce a reaction on the surface of the substrate without unwanted impurities in the thin film. Sufficient vapor pressure ensures that molecules of the source compound are present at the substrate surface in sufficient concentration to enable a complete self-saturating reaction. Sufficient thermal stability ensures that the source compound will not be subject to the thermal decomposition which produces impurities in the thin film.

Examples of ALD growth conditions for the titanium precursor, the first ruthenium precursor, and the second ruthenium precursor disclosed herein include, but are not limited to:
(1) Substrate temperature: 200-300° C.
(2) Evaporator temperature (metal precursor temperature): 20-70° C.
(3) Reactor pressure: 0.01-10 Torr
(4) Argon or nitrogen carrier gas flow rate: 0-100 sccm
(5) Reactive gas (co-reactant) pulse time: 0.01-1 sec. Pulse sequence (metal complex/purge/reactive gas/purge): will vary according to chamber size
(6) Number of cycles: will vary according to desired film thickness.

In further embodiments, the methods described herein may be performed under conditions to provide conformal growth, for example, for a first film. As used herein, the term “conformal growth” refers to a deposition process wherein a film is deposited with substantially the same thickness along one or more of a bottom surface, a sidewall, an upper corner, and outside a feature. “Conformal growth” is also intended to encompass some variations in film thickness, e.g., the film may be thicker outside a feature and/or near a top or upper portion of the feature compared to the bottom or lower portion of the feature.

The conformal growth cycle may comprise performing super cycles as described above under conformal conditions such that conformal growth occurs. Conformal conditions include, but are not limited to temperature (e.g., of substrate, titanium precursor, first ruthenium precursor, second ruthenium precursor, purge gas, co-reactant, etc.), pressure (e.g., during delivery of titanium precursor, first ruthenium precursor, second ruthenium precursor, purge gas, co-reactant, etc.), amount of titanium precursor, first ruthenium precursor, second ruthenium precursor, and/or co-reactant delivered, length of purge time and/or amount of purge gas delivered. In various aspects, the substrate may comprise one or more features where conformal growth may occur.

In various aspects, the feature may be a via, a trench, contact, dual damascene, etc. A feature may have a non-uniform width, also known as a “re-entrant feature,” or a feature may have substantially uniform width.

In one or more embodiments, a first film and/or a ruthenium-containing film grown following the methods described herein may have substantially no voids and/or hollow seams.

In any embodiments, the methods described herein can further comprising annealing the as-deposited first film, the as-deposited ruthenium-containing film, or both at higher temperatures. In other words, annealing can be performed after the last cycle for forming the first film and/or the last cycle for forming the ruthenium-containing film. The annealing step helps to provide a quality ruthenium film having low impurities and low resistivity.

Therefore, in some embodiments, the as-deposited first film, the as-deposited ruthenium-containing film, or both may be annealed under vacuum, or in the presence of an inert gas such as Ar or N₂, or a reducing agent such as H₂ or NH₃, or a combination thereof such as, for example, 5% H₂ in Ar or 5% NH₃ in Ar. Without being bound by theory, the annealing step may remove incorporated carbon, oxygen and/or nitrogen to reduce the resistivity and to further improve film quality by densification at elevated temperatures. Annealing may be performed at a temperature of greater than or equal to about 300° C., greater than or equal to about 400° C., or about 500° C.; from about 300° C. to about 500° C. or about 400° C. to about 500° C.

The first films and ruthenium-containing films formed from the methods described herein can have a lower resistivity. In some embodiments, a first film may have resistivity of greater than or equal to about 20 μΩ-cm, greater than or equal to about 40 μΩ-cm, greater than or equal to about 60 μΩ-cm, greater than or equal to about 80 μΩ-cm, greater than or equal to about 100 μΩ-cm, greater than or equal to about 250 μΩ-cm, greater than or equal to about 500 μΩ-cm, greater than or equal to about 1000 μΩ-cm, greater than or equal to about 1500 μΩ-cm, greater than or equal to about 2000 μΩ-cm, greater than or equal to about 2500 μΩ-cm, or about 3000 μΩ-cm; or from about 20 μΩ-cm to about 3000 μΩ-cm, about 100 μΩ-cm to about 3000 μΩ-cm, about 500 μΩ-cm to about 3000 μΩ-cm, about 100 μΩ-cm to about 2000 μΩ-cm, about 100 μΩ-cm to about 1000 μΩ-cm, about 100 μΩ-cm to about 500 μΩ-cm. In some embodiments, the resistivity of the first film can be lowered following annealing of the first film, for example, to a resistivity of greater than or equal to about 10 μΩ-cm, greater than or equal to about 20 μΩ-cm, greater than or equal to about 50 μΩ-cm, greater than or equal to about 100 μΩ-cm, greater than or equal to about 250 μΩ-cm, or about 500 μΩ-cm; or from about 10 μΩ-cm to about 500 μΩ-cm or about 20 μΩ-cm to about 250 μΩ-cm.

The resistance measurements noted above may be achieved in first films prepared by the methods described herein having a thickness of about 1 nm to about 20 nm, about 1 nm to about 15 nm, about 2 nm to about 15 nm, about 2 nm to about 10 nm, or about 1 nm to about 5 nm measured by XRF.

Advantageously, the films formed from the processes described herein can have reduced roughness. For example, the first film can have roughness of less than or equal to about 2 nm, less than or equal to about 1.8 nm, less than or equal to about 1.6 nm, less than or equal to about 1.4 nm, less than or equal to about 1.2 nm, or about 1 nm, as measured by AFM; or from about 1 nm to about 2 nm, about 1 nm to about 1.8 nm, about 1 nm to about 1.6 nm, or about 1 nm to about 1.4 nm, as measured by AFM. Additionally or alternatively, the ruthenium-containing film can have roughness of less than or equal to about 1.0 nm, less than or equal to about 0.8 nm, less than or equal to about 0.65 nm, less than or equal to about 0.4 nm, or about 0.2 nm, as measured by AFM; or from about 0.2 nm to about 1.0 nm, about 0.2 nm to about 0.8 nm, or about 0.2 nm to about 0.65 nm, as measured by AFM.

### Applications

The films formed from the processes described herein are useful for memory and/or logic applications, such as dynamic random access memory (DRAM), complementary metal oxide semi-conductor (CMOS) and 3D NAND, 3D Cross Point and ReRAM.

Reference throughout this specification to “one embodiment,” “certain embodiments,” “one or more embodiments” or “an embodiment” means that a particular feature, structure, material, or characteristic described in connection with the embodiment is included in at least one embodiment of the present technology. Thus, the appearances of the phrases such as “in one or more embodiments,” “in certain embodiments,” “in one embodiment” or “in an embodiment” in various places throughout this specification are not necessarily referring to the same embodiment of the present technology. Furthermore, the particular features, structures, materials, or characteristics may be combined in any suitable manner in one or more embodiments.

Although the present technology herein has been described with reference to particular embodiments, it is to be understood that these embodiments are merely illustrative of the principles and applications of the present technology. It will be apparent to those skilled in the art that various modifications and variations can be made to the method and apparatus of the present technology without departing from the spirit and scope of the present technology. Thus, it is intended that the present technology include modifications and variations that are within the scope of the appended claims and their equivalents. The present technology, thus generally described, will be understood more readily by reference to the following examples, which is provided by way of illustration and is not intended to be limiting.

### EXAMPLES

(DMBD)Ru(CO)₃ (also referred to as RuDMBD) and TDMAT were utilized as the precursor in the following examples. Methods of preparing (DMBD)Ru(CO)₃ are known in the art. For example, see U.S. 2011/0165780, which is incorporated herein by reference in its entirety.

Unless otherwise indicated, a ruthenium-titanium nitride (RuTiN) film was deposited using (DMBD)Ru(CO)₃ and TDMAT in an ALD process in a CN1 ALD/CVD reactor with the following conditions:
i. Temperatures of 225° C. and pressure of 0.94 Torr in an argon atmosphere;
ii. TDMAT at 50° C., delivered in a titanium cycle as follows to a substrate: 1 second pulse TDMAT (bubbler), 10 seconds purge with argon, hydrazine co-reactant pulse 0.075 s, and purge 10 seconds with argon.
iii. (DMBD)Ru(CO)₃ at 40° C., delivered in a ruthenium cycle as follows to a substrate: 1 second pulse (DMBD)Ru(CO)₃ (bubbler), 10 seconds purge with argon, hydrazine co-reactant pulse 0.075 s, and purge 10 seconds with argon.
iv. Super cycles including 1 titanium cycle followed by “n” number of ruthenium cycles were used to deposit a RuTiN film except for when 2 titanium cycles were performed followed by 3 ruthenium cycles.
v. Ti/Ru cycle ratio=1/n and indicates relative Ti concentration in RuTiN film.
vi. If annealing of the RuTiN film occurred, the films were either annealed in a reactor soon after deposition or exposed in air for short period of time (e.g., less than or equal to 2 minutes) and reloaded into the reactor under vacuum for annealing.
vii. Resistivity for RuTiN films was based on ellipsometer thickness unless otherwise noted.

### Example 1

### Average Growth Rate: Dependence on Ti/Ru Cycle Ratio

RuTiN films having a thickness from 13-20 nm were grown on three substrates, Al₂O₃, SiO₂, and WCN, via the above ALD conditions using various super cycles depending on Ti/Ru cycle ratio as shown below in Table 1.

TABLE 1

| | |
|---|---|
| Ti/Ru Cycle Ratio | Number of Super Cycles |

| | | |
|---|---|---|
| 0.00 | (Ru only) | 100 |
| 0.10 | (1 Ti/10 Ru) | 9 |
| 0.20 | (1 Ti/5 Ru) | 20 |
| 0.33 | (1 Ti/3 Ru) | 33 |
| 0.50 | (1 Ti/2 Ru) | 47 |
| 1.00 | (1 T1/1 Ru) | 70 |

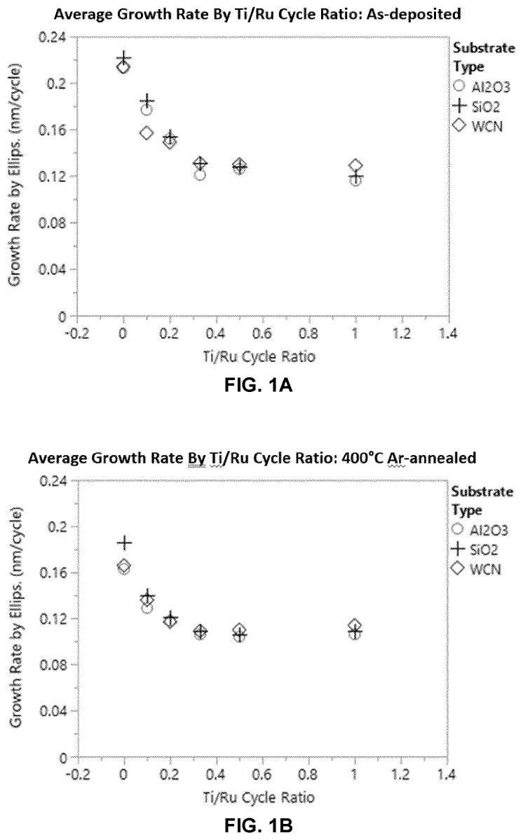

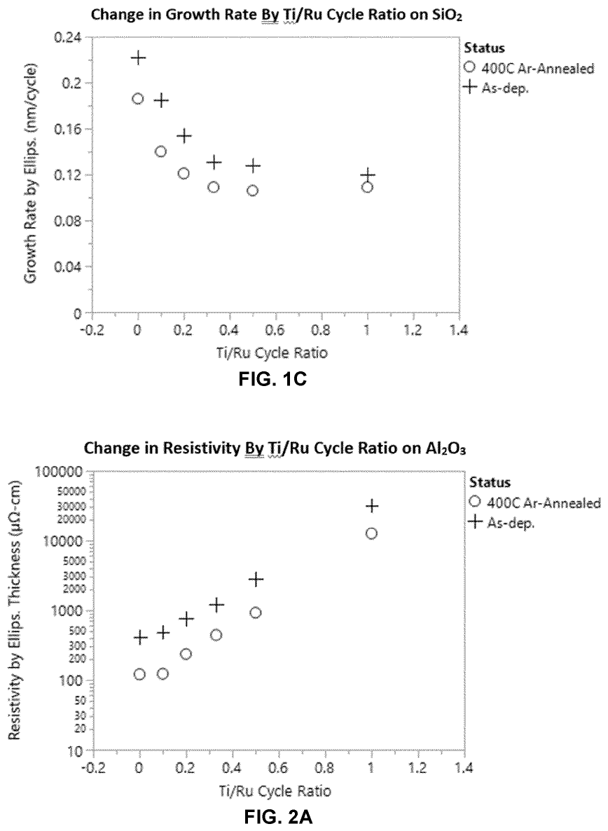

Thus, for example, RuTiN films having a Ti/Ru cycle ratio of 0.1 were each grown on an Al₂O₃, SiO₂, and WCN, and so on. The average growth rate of the RuTiN films (“as-deposited”) formed on the three substrates with the above Ti/Ru cycle ratios is shown in FIG. 1A.

The RuTiN films formed as described above also underwent post-deposition annealing at 400° C. in the presence of argon. In other words annealing was performed after the last super cycle was completed. The average growth rate of the RuTiN films formed on the three substrates with the above Ti/Ru cycle ratios is shown in FIG. 1B. FIG. 1C compares the growth rate of the RuTiN films grown on SiO₂ (“as-deposited”) and the growth rate of the annealed RuTiN films grown on SiO₂, which indicates film densification upon annealing. A steady growth rate was reached with a Ti/Ru cycle ratio greater than or equal to 0.33.

### Example 2

### Resistivity: Dependence on Ti/Ru Cycle Ratio and Effect of Annealing

Resistivity was measured for RuTiN films having at thickness from 13-20 nm grown on three substrates, Al₂O₃, SiO₂, and WCN, via the above ALD conditions using various super cycles depending on Ti/Ru cycle ratio as shown in Table 1. Resistivity was also measured for annealed RuTiN films formed as described above.

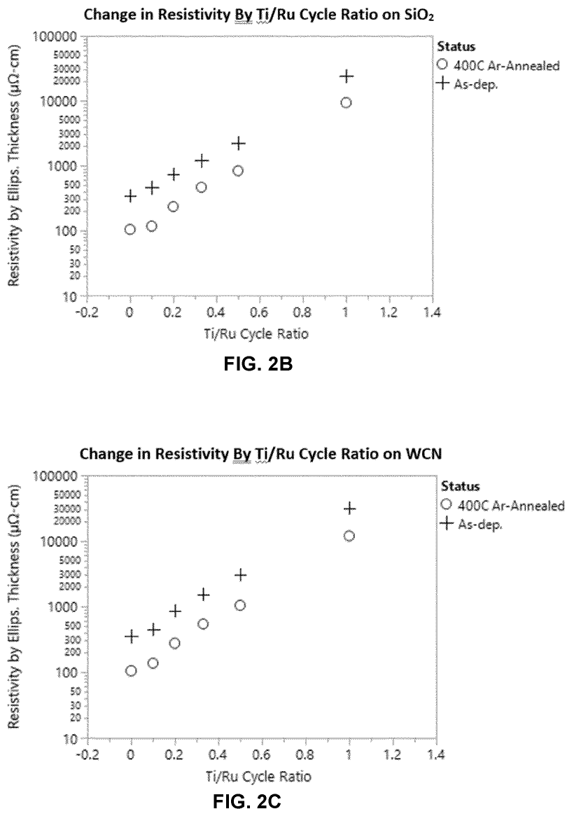

FIG. 2A compares resistivity of the RuTiN films grown on Al₂O₃ (“as-deposited) with the resistivity of the annealed RuTiN films grown on Al₂O₃. FIG. 2B compares resistivity of the RuTiN films grown on SiO₂ (“as-deposited) with the resistivity of the annealed RuTiN films grown on SiO₂. FIG. 2C compares resistivity of the RuTiN films grown on WCN (“as-deposited) with the resistivity of the annealed RuTiN films grown on WCN. Resistivity increased with increased Ti/Ru cycle ratio and annealing lowered resistivity.

### Example 3

### XPS Analysis of Thick RuTiN Films on SiO₂

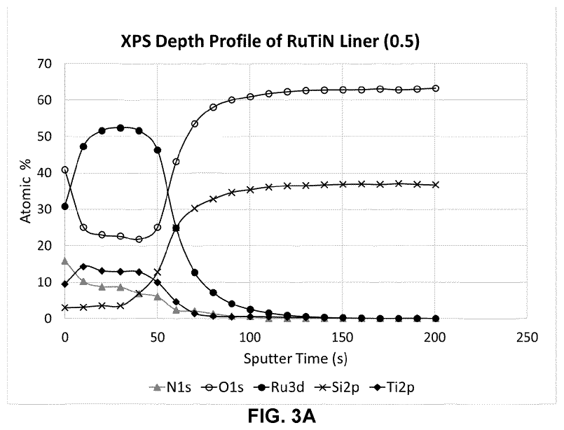

XPS analysis of a RuTiN film formed on SiO₂ with a Ti/Ru cycle ratio of 1:2 (0.5) was performed. The results confirm the existence of Ru, Ti and N in the film, and the presence of oxygen due to air exposure as shown in FIG. 3A.

### Example 4

### Resistivity of Thin v. Thick RuTiN Films

RuTiN films having a thickness from 13-20 nm (“thick films”) were grown on three substrates, Al₂O₃, SiO₂, and WCN, via the above ALD conditions using various super cycles depending on Ti/Ru cycle ratio as shown in Table 1. RuTiN films having a thickness from 2-5 nm (“thin films”) were grown on two substrates, Al₂O₃ and SiO₂, via the above ALD conditions using various super cycles depending on Ti/Ru cycle ratio as shown below in Table 2.

TABLE 2

| Ti/Ru Cycle Ratio | Number of Super Cycles |
|---|---|
| 0.25 (1 Ti/4 Ru) | 9 |
| 0.33 (1 Ti/3 Ru) | 8 |
| 0.50 (1 Ti/2 Ru) | 10 |
| 0.67 (2 Ti/3 Ru) | 6 |
| 1.00 (1 Ti/1 Ru) | 22 |

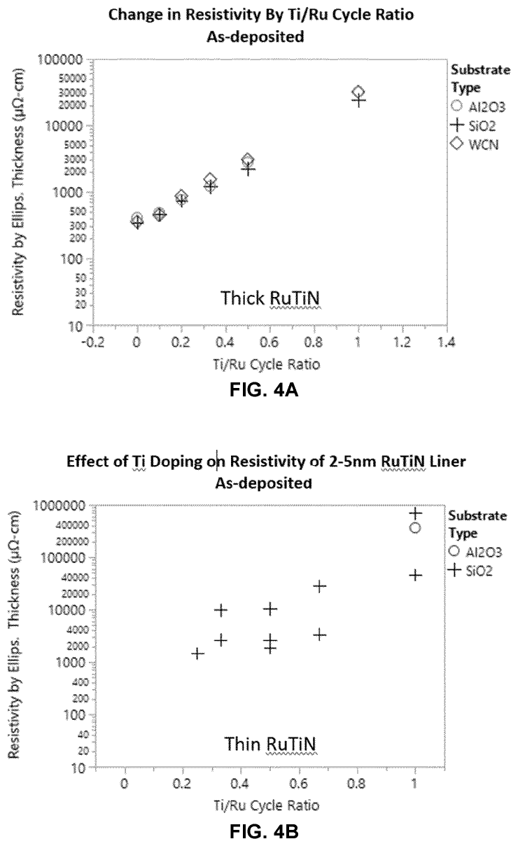

Resistivity was measured for the thick films and the thin films. FIG. 4A shows the change in resistivity for the as-deposited thick films with the Ti/Ru cycle ratios in Table 1. FIG. 4B shows the change in resistivity for the as-deposited thin films with the Ti/Ru cycle ratios in Table 2. The results indicate that both thick and thin RuTiN films have a similar resistivity trend with the Ti/Ru cycle ratio on SiO₂, but a thicker film on Al₂O₃ is needed to become conductive.

### Example 5

### Resistivity of Thin v. Thick RuTiN Films After Annealing

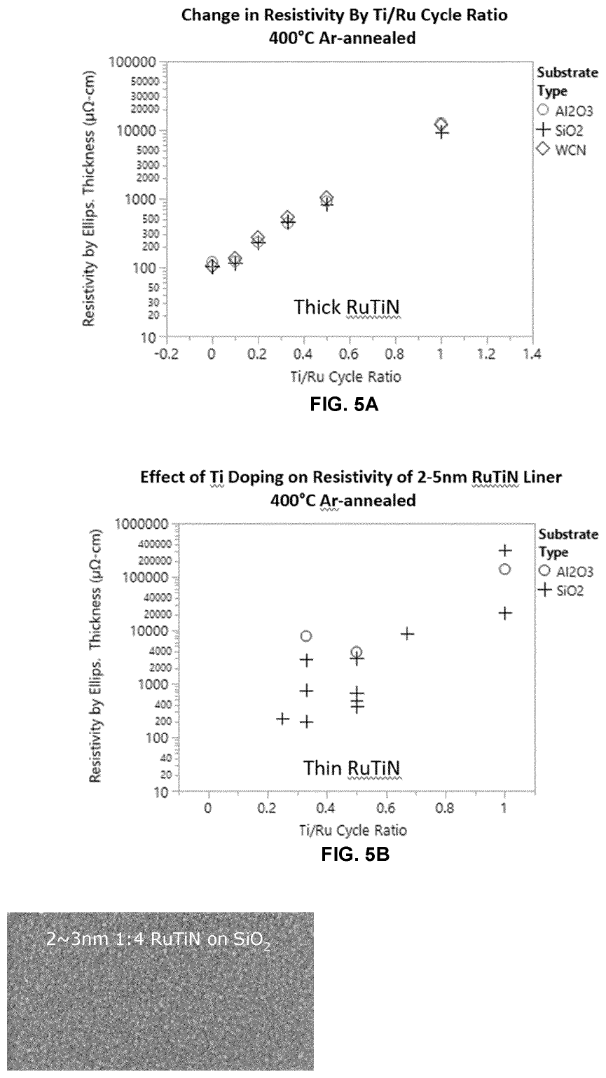

The thick and thin films from Example 4 underwent post-deposition annealing at 400° C. in the presence of argon as described above. Resistivity was measured for the annealed thick films and the annealed thin films. FIG. 5A shows the change in resistivity for the annealed thick films with the Ti/Ru cycle ratios in Table 1. FIG. 5B shows the change in resistivity for the annealed thin films with the Ti/Ru cycle ratios in Table 2.

### Example 6

### Comparison of Sheet Resistance of Various Liner Materials

Sheet resistance for various liner materials on 100 nm thermal SiO₂ was determined as shown in Table 3.

TABLE 3

| | Thickness | Sheet Resistance |
|---|---|---|
| Liner Material | (nm) | (kΩ/sq) |
| TiN | 3-5 | ≥8 |
| WCN | 3-5 | ≥13 |
| RuTiN (as-deposited) | 3-5 | 4.6 |
| Annealed RuTiN | 3-4 | 1.2 |

The as-deposited RuTiN liner material was formed via the above ALD conditions with Ti/Ru cycle ratio of 1:2 (0.5). The annealed RuTiN liner material was formed via the above ALD conditions with Ti/Ru cycle ratio of 1:2 (0.5) and underwent post-deposition annealing at 400° C. in the presence of argon as described above. The as-deposited RuTiN liner material and the annealed RuTiN liner material both had lower sheet resistance than TiN.

### Example 7

### Roughness of RuTiN Films on Various Substrates

Roughness was determined for annealed RuTiN films formed on SiO₂ via the above ALD conditions with the Ti/Ru cycle ratios as shown in Table 4 below and annealed as described above. Unless otherwise indicated, roughness was measured by Atomic force microscopy (AFM).

TABLE 4

| Ti/Ru Cycle Ratio | Film Thickness | Roughness, Rq |
|---|---|---|
| 1:4 | 2-3 nm | 0.51 nm |
| 1:3 | 2-3 nm | 0.45 nm |
| 1:2 | 2-3 nm | 0.49 nm |
| 2:3 | 2-3 nm | 0.49 nm |
| 1:1 | 2-3 nm | 0.40 nm |

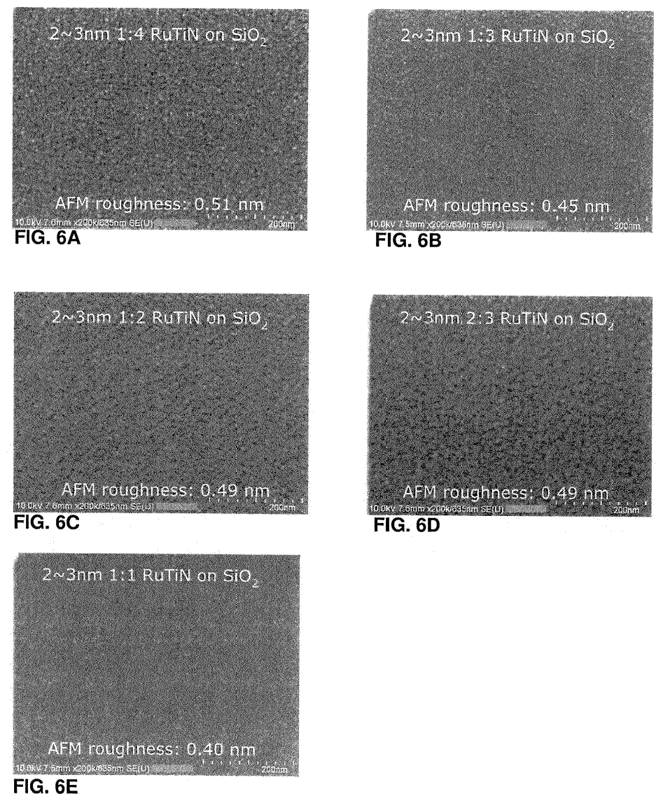

SEM images of the films in Table 4 are shown in FIGS. 6A-6E.

Roughness was determined for annealed RuTiN films formed on 4 nm Al₂O₃/100 nm SiO₂ substrate (“Al₂O₃ substrate”) and on 25 nm Al₂O₃/native SiO₂ substrate (“thick Al₂O₃ substrate” or “Al₂O₃_thick on Si”) via the above ALD conditions with the Ti/Ru cycle ratios as shown in Table 5 below and annealed as described above. Roughness was measured by Atomic force microscopy (AFM).

TABLE 5

| Substrate | Ti/Ru Cycle Ratio | Film Thickness | | Roughness, Rq |
|---|---|---|---|---|
| Al₂O₃ | 1:3 | 4 | nm | 1.29 nm |
| Al₂O₃ | 1:2 | ~3.5 | nm | 1.20 nm |
| Al₂O₃ | 1:1 | ~3 | nm | 0.81 nm |
| thick Al₂O₃ | 1:1 | ~3 | nm | 0.57 nm |

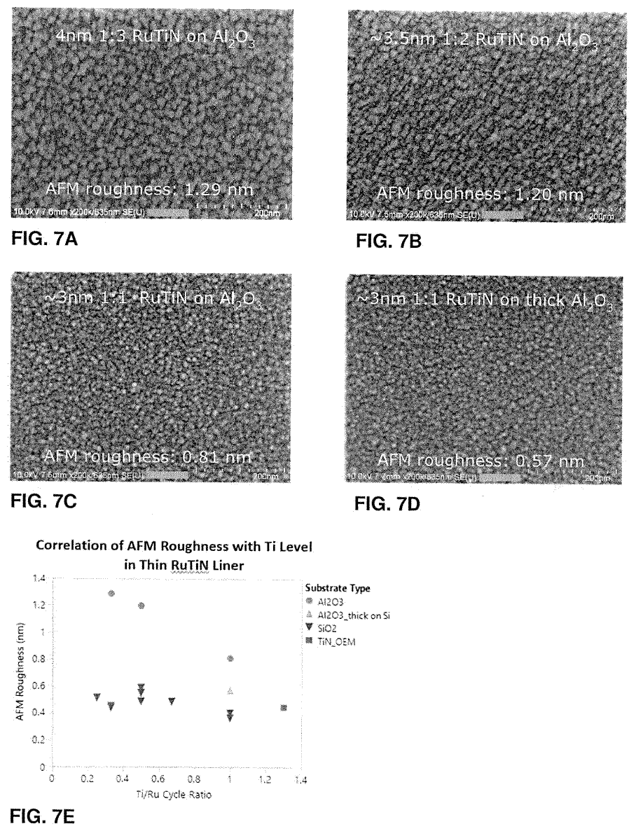

SEM images of the films in Table 5 are shown in FIGS. 7A-7D. FIG. 7E is a graphical representation of AFM roughness (nm) vs. Ti/Ru cycle ratio for annealed films formed in Tables 4 and 5 as well as RuTiN films formed on a TiN_OEM substrate via the above ALD conditions.

### Example 8

### Comparison of Roughness of Ru Films Formed on RuTiN Films and Ru Films Formed without a Liner Directly on a Substrate

Roughness was determined for Ru films formed directly on an SiO₂ substrate and Ru films formed on a RuTiN film liner on SiO₂ or Al₂O₃/100 nm SiO₂ (“Al₂O₃/SiO₂”) via the above ALD conditions with the Ti/Ru cycle ratios as shown in Table 6 below. The Ru films were formed using 55 ruthenium cycles on RuTiN liners and 40 ruthenium cycles on substrates without liners as described above. Unless otherwise indicated, roughness was measured by Atomic force microscopy (AFM).

TABLE 6

| | | Ti/Ru Cycle | Ru Film | |
|---|---|---|---|---|
| Substrate | Liner | Ratio | Thickness | Roughness, Rq |
| SiO₂ | No | N/A | 5.5 nm | 0.88 nm |
| SiO₂ | No | N/A | 7.2 nm | 1.09 nm |
| Al₂O₃/SiO₂ | No | N/A | 5.1 nm | 1.87 nm |
| SiO₂ | RuTiN | 1:2 | 6.4 nm | 0.52 nm |
| | (2-3 nm) | | | |
| Al₂O₃/SiO₂ | RuTiN | 1:2 | 6.4 nm | 1.37 nm |
| | (2-3 nm) | | | |

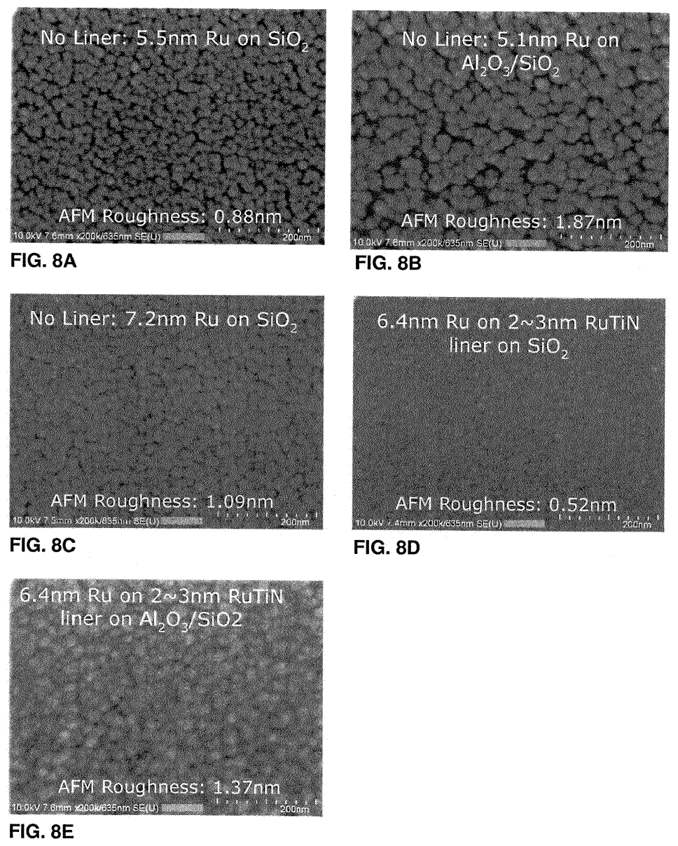

SEM images of the films in Table 6 are shown in FIGS. 8A-8E.

### Example 9

### Comparison of Roughness of Ru Films Formed on Various Liners

Ru films were formed via ALD on the following liners on SiO₂: RuTiN, TiN that was deposited on 100 nm SiO₂ (“TiN”), TiN_OEM, and WCN. The ruthenium film can include delivering the first ruthenium precursor, the second nitrogen-containing co-reactant, and the purge gas to the substrate. The Ru films were formed using 55 ruthenium cycles on RuTiN liners and 40 ruthenium cycles on substrates without liners as described above.

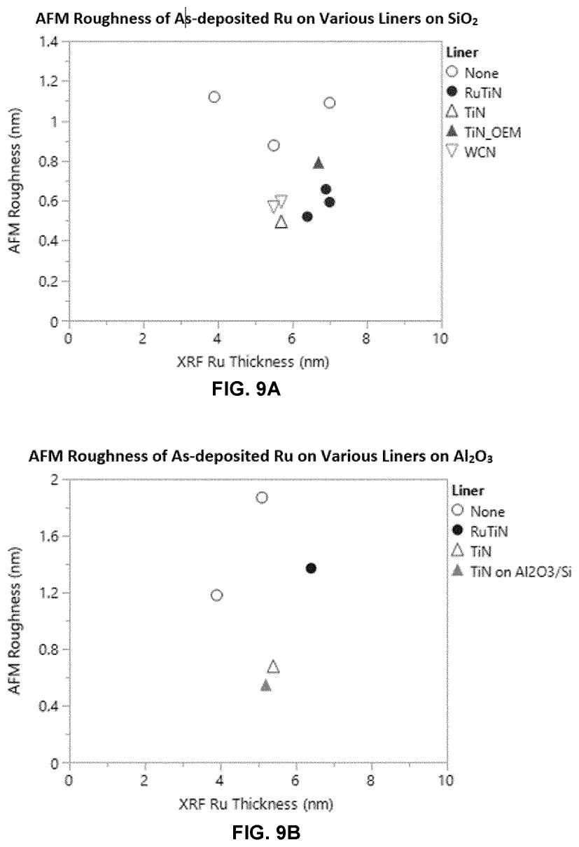

The RuTiN liner was formed via the ALD methods described above with a Ti/Ru cycle ratio of 1:2 (0.5). A Ru film was also formed directly on SiO₂ without a liner. A comparison of roughness of the Ru films formed is shown in FIG. 9A.

Ru films were also formed via ALD on the following liners on Al₂O₃/100 nm SiO₂: RuTiN, TiN, and TiN on Al₂O₃ on Si substrate with native oxide (“TiN on Al₂O₃/Si”). The RuTiN liner was formed via the ALD methods described above with a Ti/Ru cycle ratio of 1:2 (0.5). A Ru film was also formed directly on 4 nm Al₂O₃/100 nm SiO₂ without a liner. A comparison of roughness of the Ru films formed is shown in FIG. 9B.

### Example 10

### Roughness Dependence on Liner Thickness

Roughness was determined for annealed RuTiN films formed on 100 nm SiO₂ or 4 nm Al₂O₃/100 nm SiO₂ via the above ALD conditions with the Ti/Ru cycle ratios as shown in Table 7 below and annealed as described above.

TABLE 7

| | Ti/Ru Cycle | | |
|---|---|---|---|
| Substrate | Ratio | Liner Thickness | Roughness, Rq |
| SiO₂ | 1:2 | 2 nm | 0.49 nm |
| SiO₂ | 1:2 | 3 nm | 0.55 nm |
| SiO₂ | 1:2 | 5 nm | 0.59 nm |
| SiO₂ | 1:2 | 8 nm | 0.62 nm |
| Al₂O₃ | 1:2 | 3.5 nm | 1.20 nm |

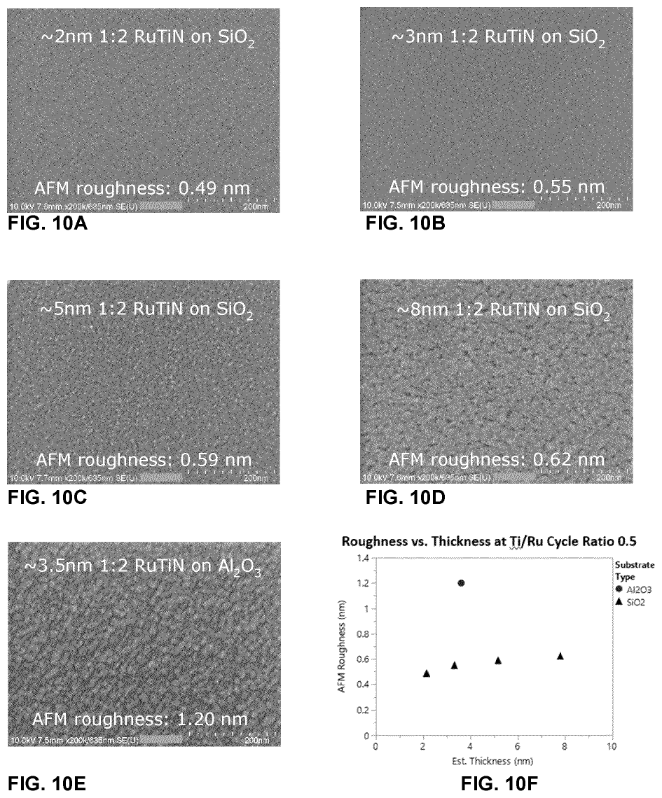

SEM images of the films in Table 7 are shown in FIGS. 10A-10E. FIG. 10F shows a graph of roughness v. film thickness for the films in Table 7.

### Example 11

### Film Formation in a Via

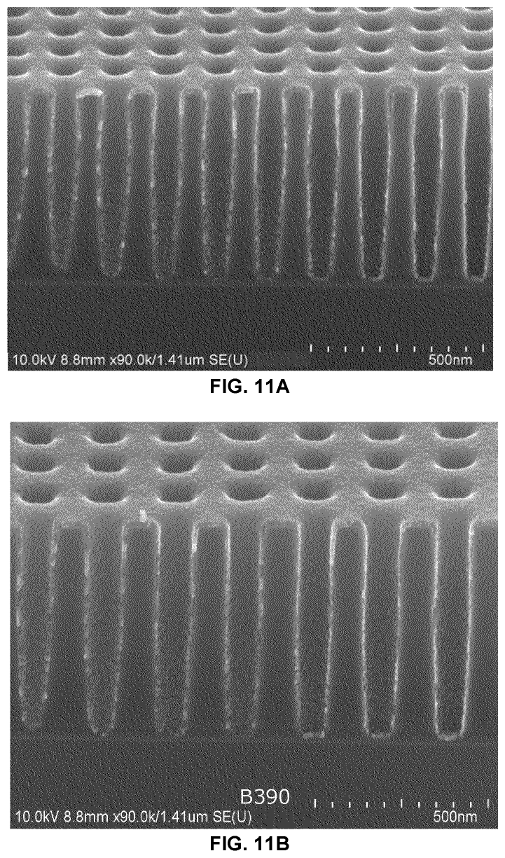

A 3 nm thick RuTiN liner was deposited via the ALD methods described above with a Ti/Ru cycle ratio of 1:2 (0.5) and 10 super cycles onto a via structure. A 6.5 nm thick Ru film was then deposited with 55 ruthenium cycles on top of the RuTiN liner. FIGS. 11A and 11B are cross-section SEM images of the via structure coated with the Ru film on top of the RuTiN liner.

All publications, patent applications, issued patents and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

The words “comprise”, “comprises”, and “comprising” are to be interpreted inclusively rather than exclusively.

1. A method for forming a ruthenium-containing film on a substrate comprising:
a first step of forming a first film on a surface of the substrate comprising:
(i) delivering a titanium precursor and a first nitrogen-containing co-reactant to the substrate; and
(ii) delivering a first ruthenium precursor and a second nitrogen-containing co-reactant to the substrate to form the first film; and
a second step of forming the ruthenium-containing film on at least a portion of the first film comprising delivering a second ruthenium precursor and a third co-reactant to the substrate and/or the first film.

2. The method of claim 1, wherein the first step, the second step, or both are performed at temperature of less than or equal to about 300° C. and/or the first step, the second step, or both are performed in an inert atmosphere.

3. (canceled)

4. (canceled)

5. The method of claim 1, wherein the first film comprises ruthenium-titanium nitride.

6. The method of claim 1, wherein the titanium precursor corresponds in structure to Formula I:
[R¹R²N]₄Ti (Formula I)
wherein R¹ and R² are each independently a C₁-C₆-alkyl.

7. (canceled)

8. The method of claim 1, wherein the titanium precursor is selected from the group consisting of tetrakis(dimethylamido)titanium, tetrakis(ethylmethylamido)titanium, and tetrakis(diethylamido) titanium and/or
wherein the first ruthenium precursor comprises (η⁴-2,3-dimethylbuta-1,3-diene)tricarbonylruthenium ((DMBD)Ru(CO)₃), (η⁴-buta-1,3-diene)tricarbonylruthenium ((BD)Ru(CO)₃), (1,3-cyclohexadienyl)tricarbonylruthenium ((CHD)Ru(CO)₃), (η⁴-2-methylbuta-1,3-diene)tricarbonylruthenium, or triruthenium dodecacarbonyl Ru₃(CO)₁₂; and the second ruthenium precursor comprises (η⁴-2,3-dimethylbuta-1,3-diene)tricarbonylruthenium ((DMBD)Ru(CO)₃), (η⁴-buta-1,3-diene)tricarbonylruthenium ((BD)Ru(CO)₃), (1,3-cyclohexadienyl)tricarbonylruthenium ((CHD)Ru(CO)₃), (η⁴-2-methylbuta-1,3-diene)tricarbonylruthenium, triruthenium dodecacarbonyl Ru₃(CO)₁₂, (ethylbenzyl)(1-ethyl-1,4-cyclohexadienyl)ruthenium (Ru(EtBz)(EtCHD)), bis(ethylcyclopentadienyl)ruthenium (Ru(EtCp)₂), (cyclopentadienyl)(ethyl)biscarbonylruthenium (Cp(Et)Ru(CO)₂), or (N,N′-diisopropylacetoamidinato)biscarbonylruthenium ((amidinate)Ru(CO)₂) and/or
wherein the first nitrogen-containing co-reactant and the second nitrogen-containing co-reactant are each independently selected from the group consisting of NH₃, alkylamine, hydrazine, alkylhydrazine, and a combination thereof, and the third co-reactant is selected from the group consisting of hydrogen, hydrogen plasma, nitrogen plasma, ammonia plasma, oxygen, air, water, a borane, a silane, ozone, NH₃, alkylamine, hydrazine, alkylhydrazine, and a combination thereof.

9. (canceled)

10. (canceled)

11. (canceled)

12. (canceled)

13. The method of claim 1, wherein the first step comprises:
one or more super cycles comprising:
a titanium cycle comprising delivering the titanium precursor, the first nitrogen-containing co-reactant, and a purge gas to the substrate; and
a ruthenium cycle comprising delivering the first ruthenium precursor, the second nitrogen-containing co-reactant, and the purge gas to the substrate; and

14. The method of claim 13, wherein a ratio between the titanium cycle to the ruthenium cycle is between about 1:1 to about 2:12.

15. The method of claim 1, wherein the second step comprises a further ruthenium cycle comprising delivering the second ruthenium precursor, the third co-reactant, and the purge gas to the substrate

16. The method of claim 1, wherein the first film has a Ti:Ru concentration ratio of about 1:10 to about 10:1.

17. The method of claim 1, wherein the first film has an average roughness of less than or equal to about 0.65 nm as measured by AFM and/or the ruthenium-containing film has an average roughness of less than or equal to about 1.6 nm as measured by AFM.

18. (canceled)

19. The method of claim 1, wherein the first film has a thickness of about 1 nm to about 5 nm and a resistivity of about 20 μΩ-cm to about 3000 μΩ-cm.

20. The method of claim 1, further comprising annealing the first film in an inert gas at a temperature of greater than or equal to about 400° C. and/or annealing the ruthenium-containing film in an inert gas at a temperature of greater than or equal to about 400° C.

21. (canceled)

22. (canceled)

23. The method of claim 1, wherein the first step and the second step are independently a chemical vapor deposition or an atomic layer deposition and/or wherein the first step, the second step or a combination thereof further comprises use of plasma.

24. (canceled)

25. A ruthenium-containing film comprising:
a first film disposed on a surface of a substrate, wherein the first film comprises a first reaction product of a titanium precursor and a first nitrogen-containing co-reactant; and a second reaction product of a first ruthenium precursor and a second nitrogen-containing co-reactant; and
the ruthenium-containing film disposed on at least a portion of the first film, wherein the ruthenium-containing film comprises a third reaction product of a second ruthenium precursor and a third co-reactant.

26. The ruthenium-containing film of claim 25, wherein the first film comprises a first layer disposed on the surface of the substrate, wherein the first layer comprises the first reaction product and/or wherein the first film comprises ruthenium-titanium nitride.

27. The ruthenium-containing film of claim 25, wherein the first film further comprises a second layer disposed on at least a portion of the first layer, wherein the second layer comprises the second reaction product and/or wherein the first layer further comprises ruthenium as a dopant.

28. (canceled)

29. (canceled)

30. The ruthenium-containing film of claim 25, wherein the titanium precursor corresponds in structure to Formula I:
[R¹R²N]₄Ti
wherein R¹ and R² are each independently a C₁-C₆-alkyl.

31. (canceled)

32. The ruthenium-containing film of claim 25, wherein the titanium precursor is selected from the group consisting of tetrakis(dimethylamido)titanium, tetrakis(ethylmethylamido)titanium, and tetrakis(diethylamido) titanium and/or
wherein the first ruthenium precursor comprises (η⁴-2,3-dimethylbuta-1,3-diene)tricarbonylruthenium ((DMBD)Ru(CO)₃), (η⁴-buta-1,3-diene)tricarbonylruthenium ((BD)Ru(CO)₃), (1,3-cyclohexadienyl)tricarbonylruthenium ((CHD)Ru(CO)₃), (η⁴-2-methylbuta-1,3-diene)tricarbonylruthenium, or triruthenium dodecacarbonyl Ru₃(CO)₁₂; and the second ruthenium precursor comprises (η⁴-2,3-dimethylbuta-1,3-diene)tricarbonylruthenium ((DMBD)Ru(CO)₃), (η⁴-buta-1,3-diene)tricarbonylruthenium ((BD)Ru(CO)₃), (1,3-cyclohexadienyl)tricarbonylruthenium ((CHD)Ru(CO)₃), (η⁴-2-methylbuta-1,3-diene)tricarbonylruthenium, triruthenium dodecacarbonyl Ru₃(CO)₁₂, (ethylbenzyl)(1-ethyl-1,4-cyclohexadienyl)ruthenium (Ru(EtBz)(EtCHD)), bis(ethylcyclopentadienyl)ruthenium (Ru(EtCp)₂), (cyclopentadienyl)(ethyl)biscarbonylruthenium (Cp(Et)Ru(CO)₂), or (N,N′-diisopropylacetoamidinato)biscarbonylruthenium ((amidinate)Ru(CO)₂) and/or
wherein the first nitrogen-containing co-reactant, and the second nitrogen-containing co-reactant are each independently selected from the group consisting of NH₃, H₂, hydrazine, alkylhydrazine, and a combination thereof, and the third co-reactant is independently selected from the group consisting of hydrogen, hydrogen plasma, nitrogen plasma, ammonia plasma, oxygen, air, water, a borane, a silane, ozone, NH₃, H₂, hydrazine, alkylhydrazine, and a combination thereof.

33. (canceled)

34. (canceled)

35. (canceled)

36. (canceled)

37. The ruthenium-containing film of claim 25, wherein the first film has one or more of:
(i) a Ti:Ru concentration ratio of about 1:10 to 10:1;
(ii) an average roughness of less than or equal to about 0.65 nm as measured by AFM; and
(iii) a thickness of about 1 nm to about 5 nm and a resistivity of about 20 μΩ-cm to about 3000 μΩ-cm.

38. (canceled)

39. The ruthenium-containing film of claim 25, wherein the ruthenium-containing film has an average roughness of less than or equal to about 1.6 nm as measured by AFM.

40. (canceled)

41. (canceled)
